(19) United States
(12) Patent Application Publication
(10) Pub. No.: US 2024/0328500 A1
(43) Pub. Date: Oct. 3, 2024

(54) ARRANGEMENT WITH A TRANSMISSION AND WITH A WORK MACHINE, AND SIMULATION METHOD

(71) Applicant: Flender GmbH, Bocholt (DE)

(72) Inventors: Volker Düvel, Bocholt (DE); DIRK SCHROER, Rhede (DE); SIMON BECKA, Wesel (DE)

(73) Assignee: Flender GmbH, Bocholt (DE)

(21) Appl. No.: 18/034,544

(22) PCT Filed: Oct. 26, 2021
(86) PCT No.: PCT/EP2021/079606

§ 371 Date: Apr. 28, 2023

(30) Foreign Application Priority Data
Oct. 29, 2020 (EP) 20204725.4

(51) Int. Cl. F16H 57/025; F16D 3/06; F16H 57/00; F16H 57/02; F16H 57/023; G06F 30/17

(52) U.S. Cl. CPC F16H 57/025; F16D 3/06; F16H 57/0037; F16H 57/023; G06F 30/17; F16H 2057/02043

(57) ABSTRACT

An arrangement includes a drive-side transmission with an output shaft of the transmission, which extends along an axis. A work machine with a drive shaft is connected in a rotationally fixed manner to the output shaft. To improve stability and to save space, the transmission on the work machine, by the connection between the output shaft and the drive shaft and a torque arm, is supported to the extent of at least 90% of the forces arising during operation. The connection of the output shaft and the drive shaft is configured to be flexurally stiff to support transverse forces. The axial end of the drive shaft is embodied as a hollow shaft. The axial end of the output shaft has a stub which is disposed at least partially in the hollow shaft of the drive shaft.

The invention relates to an arrangement comprising a drive-side transmission with an output shaft of the transmission, which extends along an axis, and comprising a work machine with a drive shaft connected in a rotationally fixed manner to the output shaft.

Moreover, the invention also comprises a computer-implemented method for simulating an arrangement and a corresponding computer program product for carrying out this method by means of at least one computer.

Arrangements of this type are often space-consuming and, as a result of comparatively high loads combined with the requirement for compactness, quickly tend to overload.

A potential application for a generic arrangement is shown in EP 2 989 351 A1.

US 2018/0251353 A1 discloses a drive shaft of a motor designed as a hollow shaft, which is coupled in a rotationally fixed manner radially on the inside via internal teeth to a short spline provided radially on the outside of an output shaft of a transmission supported by a torque arm.

CN 203 594 733 U discloses a transmission for an extruder, in which drive power is transmitted via spur transmission stages to a planetary gear set supported by a torque arm, the two-part output shaft of which protrudes on different sides of the transmission in order to drive the respective extruder screws. The two-part output shaft connected to a planetary carrier of the planetary gear set has two hollow shafts which are non-rotatably connected to one another via a short spline, with which the associated extruder screw can be attached via a spline or a flange screw connection.

EP 3 702 647 A1 discloses a transmission for a wind turbine, in which drive power is transmitted via a spur transmission stage from a planetary gear set supported by a torque arm to a generator, with the spur transmission stage being non-rotatably coupled via a short spline to a sun shaft designed as a hollow shaft. The spur transmission stage has an output shaft which protrudes from the transmission housing and is designed as a solid shaft.

A transmission for a wind turbine is known from US 2007/2950509 A1, in which drive power is introduced via a planetary carrier of a planetary gear set supported by a torque arm and transmitted via a sun shaft to a generator, the sun shaft being designed as a solid shaft.

Proceeding from the problems described above, the invention is based on the object of creating a reliable arrangement of the type defined at the outset, which withstands the high loads that occur while taking up moderate space.

To solve the problem, the invention proposes an arrangement of the type defined at the beginning, in which the transmission on the work machine, by means of the connection of the output shaft to the drive shaft and by means of a torque arm, is supported to the extent of at least 90% of the forces generated during operation, wherein the connection of the output shaft to the drive shaft is configured to be flexurally stiff to support transverse forces; wherein the axial end of the drive shaft is embodied as a hollow shaft; wherein the axial end of the output shaft has a stub which is at least partially disposed in the hollow shaft of the drive shaft.

The arrangement according to the invention preferably comprises a planetary gear set as the transmission and is preferably part of a roller press or a mill, e.g. a sugar mill, preferably with an individual drive, or various other applications in the industrial sector.

With regard to the transmission, the arrangement according to the invention can be referred to as “mounted so as to ride on the shaft”. This means that the output shaft of the transmission or planetary gear set is attached to the drive shaft of the work machine in such a way that the output shaft and the transmission thereon are supported against transverse forces. The torque on the transmission or transmission housing is discharged by means of a torque arm, e.g. introduced indirectly or directly into a foundation. In this case, the torque can also be discharged by means of adjacent machine elements, for example via the work machine to which the torque arm is attached. The torque arm is attached here to the transmission in such a manner that the transmission is prevented from rotating axially (with respect to the output shaft). Other degrees of freedom of movement are preferably not restricted by the torque arm.

The drive shaft of the work machine is in particular rigidly coupled to the output shaft of the transmission, so that preferably a radial offset and/or tilting capability between the drive shaft of the work machine and the output shaft of the transmission is eliminated. In particular, the axes of rotation of the drive shaft of the work machine and the output shaft of the transmission are aligned coaxially with one another, so that the axes of rotation of the drive shaft of the work machine and of the output shaft of the transmission can coincide. In the assembled state, an axial relative movement of the drive shaft of the work machine relative to the output shaft of the transmission is preferably also blocked. The drive shaft of the work machine and the output shaft of the transmission can be mutually centered. Torques arising in the arrangement can thereby be supported almost completely, in particular to the extent of at least 90%, via the torque arm. A torque to be supported that is introduced by the work machine via the drive shaft into the transmission is thus not supported at the connection point of the drive shaft of the work machine with the output shaft of the transmission, but rather is discharged via the output shaft of the transmission and, at a distance from the drive shaft of the work machine, is only supported via the torque arm. The torque to be supported that is introduced by the work machine can thus be passed on via the individual teeth of the transmission until it can be supported via the torque arm. The transmission is designed in particular as an at least single-stage, preferably multi-stage, planetary gear set, of which a toothed transmission component, for example a stationary ring gear, is firmly connected to a transmission housing, to which the torque arm can in turn be connected. The torque to be supported that is introduced by the work machine is thus conducted and supported via the individual toothings of the transmission to the transmission housing and the torque arm, so that a small installation space requirement is achieved with good stability.

In particular, the drive shaft of the work machine is designed as a hollow shaft essentially only in an axial region in which the drive shaft encompasses the output shaft of the transmission radially on the outside and is otherwise designed as a solid shaft. The region of the drive shaft that forms the hollow shaft is designed, for example, as a cylindrical depression that is introduced on an axial end face, for example by turning, coaxially with the axis of rotation of the drive shaft. The output shaft of the transmission is preferably designed as a solid shaft. A continuous cylindrical opening running coaxially to the axis of rotation in the axial direction can be avoided in the output shaft, so that the output shaft can transmit the loads that occur without significant deflection, even with a smaller nominal diameter than the drive shaft of the work machine.

The output shaft represents in particular the last shaft still to be attributed to the transmission in the direction of torque, which in particular protrudes from a transmission housing of the transmission or is connected to the drive shaft protruding into the transmission housing of the transmission. The output shaft can represent a power output of the transmission. The drive shaft represents in particular the first shaft still to be attributed to the work machine in the direction of torque, which in particular protrudes from a housing of the work machine or is connected to the output shaft protruding into the housing of the work machine. The output shaft can represent a power input of the work machine.

Owing to the flexurally stiff connection of the drive shaft of the work machine with the output shaft of the transmission, bending transverse to the axis of rotation can be avoided. Instead, in particular the transverse forces that occur can be transferred to the torque arm via the transmission and supported spatially offset to the connection point of the drive shaft of the work machine with the output shaft of the transmission. This makes it possible to save on further support in the region of the connection point of the drive shaft of the work machine with the output shaft of the transmission.

In particular, the drive shaft is supported on the output shaft via a radial support for dissipating transverse forces. The radial support is formed, for example, by a step or shoulder against which the drive shaft can rest on the output shaft, preferably in a planar manner. The radial support is in particular part of a centering feature of the drive shaft on the output shaft. For the flexurally stiff connection, the radial support acting between the drive shaft of the work machine and/or the output shaft of the transmission transversely to the rotation axis of the drive shaft of the work machine and/or the output shaft of the transmission, i.e. in particular substantially in the radial direction, can therefore be provided, via which radial support transverse forces arising in the radial direction can be supported and discharged via the transmission to the rotary support.

The drive shaft is preferably supported on the output shaft via an axial support for dissipating longitudinal forces. The axial support is formed, for example, by a step or shoulder against which the drive shaft can rest on the output shaft, preferably in a planar manner. The axial support is in particular part of a centering feature of the drive shaft on the output shaft. For the flexurally stiff connection, the axial support acting between the drive shaft of the work machine and/or the output shaft of the transmission along the axis of rotation of the drive shaft of the work machine and/or the output shaft of the transmission, i.e. in particular substantially in the axial direction, can therefore be provided, via which axial support longitudinal forces arising in the axial direction can be supported and discharged via the transmission to the rotary support.

The arrangement is preferably configured in such a manner that the transmission on the work machine is fully supported against the forces arising during operation by means of the connection of the output shaft to the drive shaft and by means of the torque arm.

A characteristic of this arrangement is that the element connecting the work machine shaft and the transmission shaft must also transmit the weight loads of the transmission and other components (motor, clutch, etc.) in addition to the drive torque. This results in high alternating bending loads at the connection.

According to the invention, it is possible to provide the short spline, which is critical for the dimensioning, on the maximum possible diameter of the output shaft or the stub. It is particularly expedient here if the outside diameter of the output shaft short spline is between 85-100% of the outside diameter of the region of the output shaft that adjoins the stub. For the purposes of the invention, the term “stub” refers only to a shaft section at the end which, in particular, does not have to have a different diameter from the rest of the shaft or is necessarily configured differently in some other way. This is because not only the drive torque but also transverse forces are transmitted via this connection.

An advantageous development of the invention provides that the drive shaft has a modular structure such that the axial end of the drive shaft is configured as a first axial section as a flange which is attached axially to a second axial section of the drive shaft, the flange forming the end axial shaft section, which is configured as a hollow shaft. In particular, this modular structure allows the use of the arrangement according to the invention with adjacent standard components. A flange can be used as standard to connect the transmission shaft and work machine shaft. The flange is preferably screwed to the drive shaft or work machine shaft.

The flange can be configured particularly cost-effectively and expediently as a cast component, in particular made of metal. In a conventional arrangement of the type defined at the outset, it is only possible under the correspondingly high loads to produce the flange from a higher-strength material. The invention also opens up the possibility of an embodiment as a cast component. A forged part is significantly more expensive than a comparable cast version.

A particularly advantageous assembly is achieved when the drive shaft in the region of the configuration as a hollow shaft has a molding; wherein a holding element by means of fastening means is fastened to the axial end of the output shaft configured as a stub in such a manner that the molding is jammed in the region between the holding element and an axial contact surface the remaining part of the output shaft. The holding element is preferably composed of metal.

In this way, the flange can be attached to the output shaft by means of the holding element and then the flange can be fastened to the drive shaft. Particularly usefully for the ease of assembly and for the strength and smooth running, in the arrangement according to the invention, the holding element, which is particularly advantageously in the form of a ring, i.e. can be configured as a holding ring, can be embodied in one piece. The arrangement according to the invention particularly preferably enables free axial accessibility to the mounting position of the holding element, in particular without an axially extending continuation of a shaft requiring a separable—at least 2-part design of the holding element.

So that the arrangement according to the invention is radially aligned as well as possible, at least one first radial drive shaft centering feature can be provided on an axial end of the drive shaft; wherein at least one radial output shaft centering feature is provided on an axial end of the output shaft to which the drive shaft is connected; wherein the two centering features are in mutual contact in a radially centering manner.

A particularly advantageous way of producing this flexural stiffness is that a second radial drive shaft centering feature which is axially spaced apart from the first radial drive shaft centering feature is provided on the axial end of the drive shaft; wherein a second radial output shaft centering feature which is axially spaced apart from the first radial output shaft centering feature is provided at the axial end of the output shaft, wherein the output shaft centering features and drive shaft centering features are assigned in pairs to two axially spaced-apart centering feature pairs and are in each case in mutual contact in a radially centering manner.

On the transmission side, the flange is preferably plugged during assembly into the output shaft, which is particularly preferably embodied as a hollow shaft with the internal short teeth and two centering seats. The bending loads are thus transmitted via the centering seats, and the torques are transmitted via the splines. The axial displacement of the components relative to one another is prevented by the holding element, preferably configured as a holding ring. This can be made undivided in the circumferential direction.

The dimensioning criterion for the flange is the maximum possible inner diameter on the transmission output shaft. This is linked to the outer diameter of the shaft via a minimum thickness ratio. With increasing torque density, the outer diameter of the transmission output shaft becomes smaller and smaller, which means that the possible inner diameter also becomes smaller. This also leads to a smaller journal on the flange, which means that the alternating bending loads that occur become the dimensioning criterion. This is where the solution according to the invention shows its strengths.

The preferred field of application of the invention is in the sector of transmissions, such as those provided on mills, e.g. sugar mills. These transmissions are preferably configured as planetary gear sets.

Advantages and configurations of the invention, which can be used individually or in combination with one another, are the subject matter of the dependent claims.

The invention also relates to a computer-implemented method for simulating an arrangement according to at least one combination of features defined by the claims, in which in particular the individual components of the arrangement are virtually mapped in a simulation environment as computer-simulated parts and their physical interactions in the simulation environment are completely or partially analyzed. Accordingly, the invention comprises on the one hand the physical structure with the features according to the invention and on the other hand also a digital twin, such as is used for the purpose of simulating the arrangement or the operation of the arrangement using at least one computer. In addition, the invention also relates to a corresponding computer program product. The computer program product includes commands used when executing the computer program product by a computer causing it to virtually map the individual components of the arrangement according to the invention in a simulation environment as computer-simulated parts and to analyze their physical interactions in the simulation environment completely or partially in order to carry out the computer-implemented method.

One aspect also relates to a data agglomerate with data packages combined in a common file or distributed across different files for imaging the three-dimensional design and/or the interactions of all components provided in the arrangement, which can be configured and refined as described above, wherein the data packets are prepared for processing by a data processing device to carry out additive manufacturing of the components of the arrangement, which can be configured and refined as described above, in particular by 3D printing, and/or to simulate the functioning mode of the arrangement, which can be configured and refined as described above. The data agglomerate can represent a virtual embodiment of the arrangement according to the invention in the manner of a so-called “digital twin”, which enables a virtual examination in the form of a simulation or a real embodiment using an additive manufacturing process. In particular, each data packet can represent a separately executed component of the arrangement according to the invention, so that the individual components can easily be put together actually and/or virtually in terms of their relative position and/or relative mobility in order to implement the interactions essential to the invention. This enables inexpensive production of prototypes and/or computer-based simulations in order to study the functioning of the arrangement according to the invention, to identify problems in the specific application and to find improvements. Individual and/or all data packages of the data agglomerate can preferably be loaded into the simulation environment of the computer-implemented method and/or the computer program product, for example as part of a database or library, and uploaded for virtual mapping as computer-simulated parts and/or their physical interactions.

Further features, characteristics and advantages of the present invention are derived from the following description with reference to the figures. In the figures, in each case schematically:

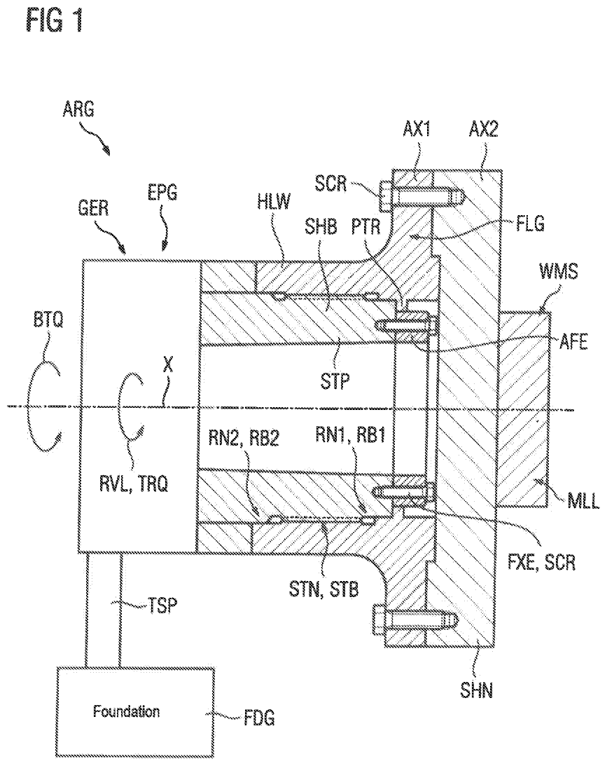

FIG. 1 shows a simplified, two-dimensional longitudinal sectional view of an arrangement according to the invention; and

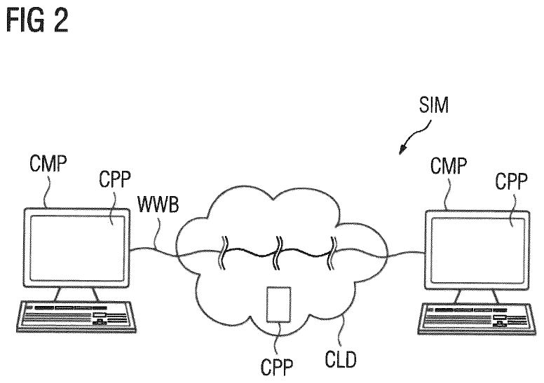

FIG. 2 shows a schematic illustration of a simulation running on a computer of an arrangement according to the invention, computer program product.

In the exemplary embodiments and figures, elements that are the same or have the same effect can each be provided with the same reference symbols. The elements shown and their proportions to one another are not to be regarded as true to scale, rather individual elements can be shown with relatively larger dimensions for better representation and/or better understanding.

FIG. 1 shows a simplified, two-dimensional longitudinal section of an arrangement ARG according to the invention with an output shaft SHB of a transmission GER, which extends along an X axis. The transmission GER is configured as a planetary gear set EPG. The output shaft SHB is connected in a rotationally fixed and flexurally stiff manner to a drive shaft SHN. The drive shaft SHN is connected to a work machine, in particular a mill MLL, in a torque-transmitting connection. The GER transmission is supported on the work machine WMS by means of the connection of the output shaft SHB to the drive shaft SHN and by means of a torque arm TSP to an extent of at least 90%—preferably completely—of the forces arising during operation. Forces BTQ (particularly bending loads, transverse forces) from the drive (not shown) of the transmission GER are introduced into the drive shaft SHN and the torque arm TSP (here in particular forces from a differential torque as a result of the transmission GER). The torque at the transmission GER or transmission housing is discharged by means of the torque arm TSP, e.g. introduced indirectly or directly into a foundation FDG.

The output shaft SHB is connected to an axial end of the drive shaft SHN. A torque TRQ with a rotational speed RVL is transmitted from the output shaft SHB to a drive shaft short spline STN of the drive shaft SHN by means of an output shaft short spline STB.

The axial end of the drive shaft SHN, which is connected to the output shaft SHB, is embodied as a hollow shaft HLW. In this case, the axial end of the output shaft SHB has a stub STP, which is at least partially disposed in the hollow shaft HLW of the drive shaft SHN.

The drive shaft SHN has a modular structure such that the axial end of the drive shaft SHN is configured as a first axial section AX1 as a flange FLG, which is attached axially to a second axial section AX2 of the drive shaft SHN, with the flange FLG forming the end-side axial shaft section, which is configured as a hollow shaft HLW. The flange FLG is fastened to the second axial section AX2 by means of screws SCR and is configured as a cast component, in particular made of metal.

The drive shaft SHN in the region of the configuration as a hollow shaft HLW has a radially inward-projecting molding PTR, wherein a holding element AFE by means of axially acting fastening means FXE, screws SCR, is fastened to the axial end of the output shaft SHB configured as a stub STP in such a manner that the molding PTR is jammed in the region between the holding element AFE and an axial contact surface of the remaining part of the output shaft SHB.

The holding element AFE is ring-shaped and configured in one piece in the circumferential direction.

A first radial drive shaft centering feature RN1 is provided at the axial end of the drive shaft SHN, and a radial output shaft centering feature RB1 is provided at the axial end of the output shaft SHB, to which the drive shaft SHN is connected, with the two centering features being in mutual contact in a radially centering manner.

The connection between the output shaft SHB and the drive shaft SHN is configured to be flexurally stiff, in that a second radial drive shaft centering feature RN2 which is axially spaced apart from the first radial drive shaft centering feature RN1 is provided on the axial end of the drive shaft SHN; wherein a second radial output shaft centering feature RB2 which is axially spaced apart from the first radial output shaft centering feature RB1 is provided at the axial end of the output shaft SHB, wherein the output shaft centering features RB1, RB2 and drive shaft centering features RN1, RN2 are assigned in pairs to two axially spaced-apart centering feature pairs and are in each case in mutual contact in a radially centering manner.

FIG. 2 shows a schematic representation of a simulation SIM of an arrangement ARG according to the invention running on a computer CMP-here on several computers CMP of a network WWB comprising a cloud CLD. The software installed on the computers CMP is a computer program product CPP which, when executed on at least one computer CMP, enables the user to influence or configure and gain knowledge on the basis of the simulation SIM carried out via screen and keyboard interfaces, so that in particular technical design decisions can be supported and verified using the simulation.

Although the invention has been illustrated and described in detail by the preferred embodiment, the invention is not limited by the disclosed examples. Variations may be devised by those skilled in the art without departing from the scope of the invention as defined by the following claims.

What is claimed is:

1.-15. (canceled)

16. An arrangement, comprising;
a work machine including a drive shaft having an axial end embodied as a hollow shaft, said drive shaft including a molding in a region of the hollow shaft;
a transmission including an output shaft connected in a rotationally fixed manner to the drive shaft with the connection of the output shaft to the drive shaft configured to be flexurally stiff to support transverse forces, the output shaft extending along an axis with an axial end having a stub which is at least partially disposed in the hollow shaft of the drive shaft;
a torque arm configured such that the torque arm and the connection between the output shaft and the drive shaft support the transmission on the work machine by at least 90% of forces arising during operation; and
a holding element fastened by fastening means to the axial end of the output shaft in such a manner that the molding is jammed in a region between the holding element and an axial contact surface of a remaining part of the output shaft.

17. The arrangement of claim 16, further comprising a radial support supporting the drive shaft on the output shaft for dissipating transverse forces.

18. The arrangement of claim 16, further comprising an axial support supporting the drive shaft on the output shaft for dissipating longitudinal forces.

19. The arrangement of claim 16, wherein the drive shaft is constructed in a modular manner such that the axial end of the drive shaft as a first axial portion is configured as a flange which is attached axially to a second axial section of the drive shaft, said flange forming at the axial end an axial shaft section which is configured as the hollow shaft.

20. The arrangement of claim 16, wherein the holding element has a round or ring-shaped configuration.

21. The arrangement of claim 19, wherein the flange is configured as a casting.

22. The arrangement of claim 16, further comprising:
an output shaft short spline provided on the axial end of the output shaft to which the drive shaft is connected; and
a drive shaft short spline provided on the axial end of the drive shaft to which the output shaft is connected.

23. The arrangement of claim 16, wherein the torque arm and the connection between the output shaft and the drive shaft completely support the transmission on the work machine against the forces arising during operation

24. The arrangement of claim 16, further comprising:
a first radial drive shaft centering feature provided on the axial end of the drive shaft; and
a first radial output shaft centering feature provided on the axial end of the output shaft to which the drive shaft is connected,
wherein the first radial drive shaft centering feature and the first radial output shaft centering features are in mutual contact in a radially centering manner.

25. The arrangement of claim 24, further comprising:
a second radial drive shaft centering feature axially spaced apart from the first radial drive shaft centering feature on the axial end of the drive shaft; and
a second radial output shaft centering feature axially spaced apart from the first radial output shaft centering feature on the axial end of the output shaft,
wherein the first and second output shaft centering features and first and second drive shaft centering features are assigned in pairs to two axially spaced-apart centering feature pairs which are in mutual contact in a radially centering manner, respectively.

26. The arrangement of claim 19, wherein the output shaft and/or the drive shaft and/or the torque arm and/or the flange are composed of metal.

27. A computer-implemented method for simulating an arrangement as set forth in claim 16, the method comprising:
virtually mapping individual components of the arrangement in a simulation environment as computer-simulated parts; and
completely or partially analyzing physical interactions of the individual components in the simulation environment.

28. A computer program product embodied as a non-transitory computer readable medium, the computer program product comprising commands used in execution of the computer program product by a computer to initiate the computer to virtually map individual components of an arrangement as set forth in claim 16 in a simulation environment as computer-simulated parts and to analyze physical interactions of the computer-simulated parts in the simulation environment completely or partially.

29. A data agglomerate, comprising data packets combined in a common file or distributed across different files for imaging three-dimensional design and/or interactions of all the components provided in an arrangement as set forth in claim 16, wherein the data packets are prepared for processing by a data processing device to carry out additive manufacturing of the components of the arrangement and/or to simulate a functioning mode of the arrangement.

30. The data agglomerate of claim 29, wherein the additive manufacturing Includes 3D printing.
